(19) United States
(12) Patent Application Publication
(10) Pub. No.: US 2006/0220227 A1
(43) Pub. Date: Oct. 5, 2006

(54) High density integrated circuit having multiple chips and employing a ball grid array (BGA) and method for making same

(75) Inventor: Len Marro, Poquott, NY (US)

Correspondence Address: VOLPE AND KOENIG, P.C., UNITED PLAZA, SUITE 1600, 30 SOUTH 17TH STREET, PHILADELPHIA, PA, 19103, US

(73) Assignee: Data Device Corporation, Bohemia, NY (US)

(21) Appl. No.: 11/243,653

(22) Filed: Oct. 5, 2005

Related U.S. Application Data
(60) Provisional application No. 60/668,172, filed on Apr. 4, 2005.

(51) Int. Cl. H01L 23/34; H01L 21/50

(52) U.S. Cl. 257/723; 257/698; 257/700; 257/691; 257/685; 438/110

(57) ABSTRACT

High density integrated circuits and more particularly to a high density integrated circuit incorporating a multiplicity of functional chips arranged on a substrate comprised of a plurality of dielectric and conductive layers which interface the semiconductor dies with a ball gate array (BGA) arranged on the underside of the substrate and wherein the main heat generating areas of the semiconductor dies are directly coupled to selected balls of the BGA for directly carrying heat from the major heat sources away from the device.

This application claims benefit to Provisional Application No. 60/668,172 which was filed on Apr. 4, 2005.

### FIELD OF INVENTION

The present invention relates to high density integrated circuits and more particularly to a high density integrated circuit incorporating a multiplicity of functional chips arranged on a common substrate comprised of a plurality of interspersed insulated dielectric and conductive layers which selectively interface terminals of the semiconductor dies to one another and to a ball grid array (BGA) arranged on the underside of the substrate and wherein the main heat generating areas of the semiconductor dies are directly coupled to selected balls of the ball grid array for directly carrying heat from the major heat sources away from the device.

### BACKGROUND

Leaded ceramic devices comprise a semiconductor die having leads typically around two or more sides of the perimeter of the device and which are typically connected to terminals on a printed circuit board arranged beneath the outwardly extending leads. These devices are typically referred to as leaded devices and in some instances leaded ceramic devices.

By providing the input/output (I/O) connections on the bottom of the package, this significantly reduces the footprint of the device when compared with a leaded ceramic device.

In addition to the above, there is a need to conduct heat away from the device in a direct and highly efficient manner.

### SUMMARY

The present invention is a plastic encapsulated ball grid array (BGA) device having the capabilities of a leaded ceramic device but with the advantages of utilizing a BGA and capable of conducting heat away from the high density device in a highly efficient manner.

The device of the present invention comprises a multichip module (MCM) and in one preferred embodiment, comprises a protocol die, plural transceiver dies and an optional random access memory (RAM) die. The semiconductor dies are bonded to a substrate which is a high thermal gradient (Tg) BT utilizing a conductive epoxy, BT being known as a high temperature type of FR4. The components of the circuit are interconnected, preferably with gold wires bonded between the semiconductor devices and printed wiring on layers of the BT multilayer substrate. This assembly is then over-molded using an epoxy compound. I/O is achieved with the attached of an array of solder balls arranged in a regular matrix of rows and columns on the bottom of the substrate yielding the finished BGA package configuration. The multilayer substrate is comprised of a plurality of alternating copper and insulating layers. Micro vias, both “blind” and “through” vias, are provided to connect surface mounted components to selected ones of the conductive layers for interconnecting terminals of different dies. Vias “Through” vias serving as heat pipes are provided to directly conduct heat from high heat concentration regions of die mounted components so as to conduct the heat preferably in the shortest practical paths available. Selected ones of the die terminals are electrically connected to selected ones of the balls in the BGA for electrical connection to external terminals/components.

Since the I/O are on the bottom of the package, the board area (i.e. the footprint of the package) is the same as the outer perimeter of the package thus significantly reducing the footprint required as compared with a leaded ceramic device having the same functional capability and components.

In another embodiment, a RAM of double the memory capacity is provided, available as well as being provided with additional devices such as a quad buffer and multibit parity checking circuits. However, any number and variety of high density devices may be produced using the design and techniques of the present invention.

### BRIEF DESCRIPTION OF THE DRAWINGS

FIGS. 1A, 1B and 1C are top, side and bottom views of a first embodiment of the invention.

FIG. 1D is a plan view of the dies embodied in the finished package showing FIGS. 1A-1C.

FIG. 1E is a detailed elevational view of the substrate.

FIG. 1F is a plan view of a common hole pattern for two layers of the substrate of FIG. 1E.

FIG. 1G is a detailed elevational view of a portion of the multilayer substrate of FIGS. 1A-1D.

FIGS. 2A, 2B and 2C respectively show top, side and bottom views of another embodiment of the present invention.

FIG. 2D shows a layout of the dies encapsulated in the finished package shown in FIGS. 2A-2C.

### DETAILED DESCRIPTION OF THE PREFERRED EMBODIMENTS

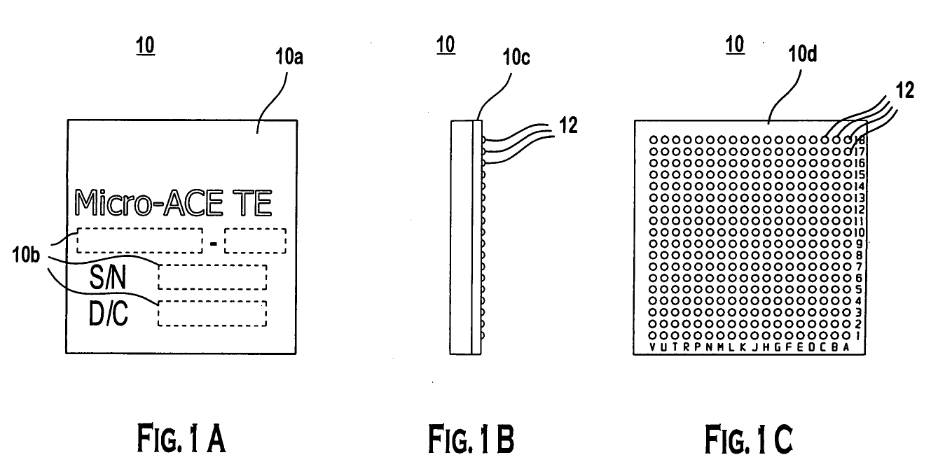

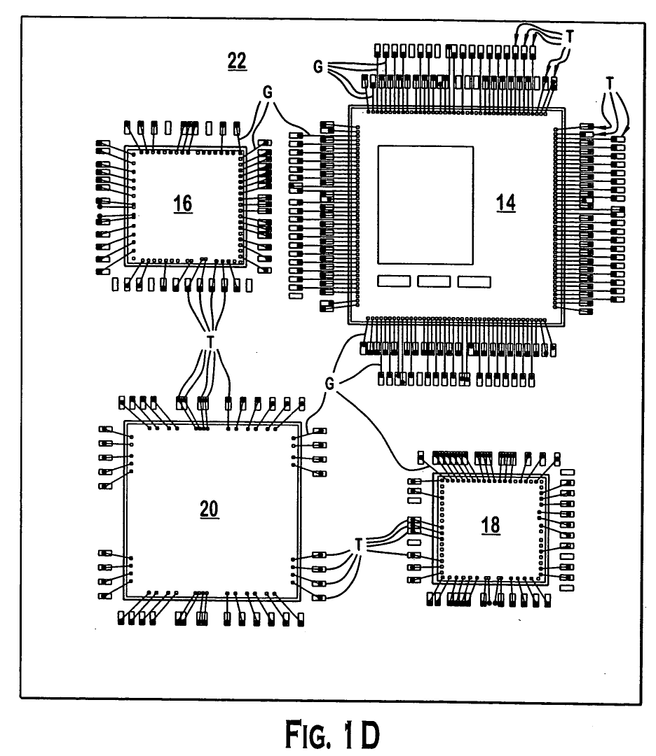

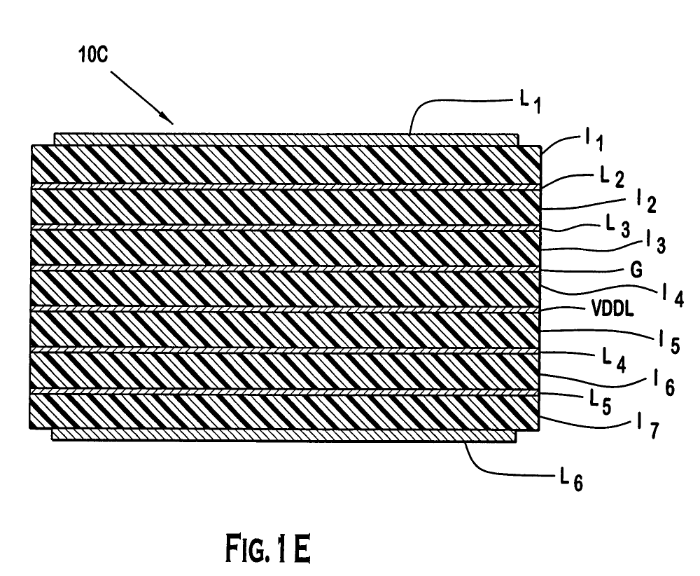

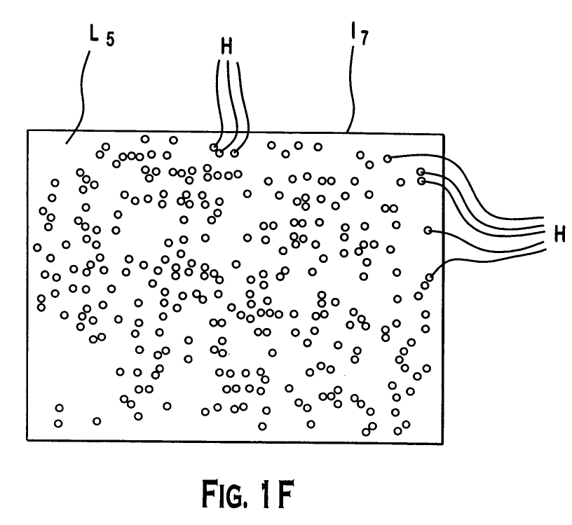

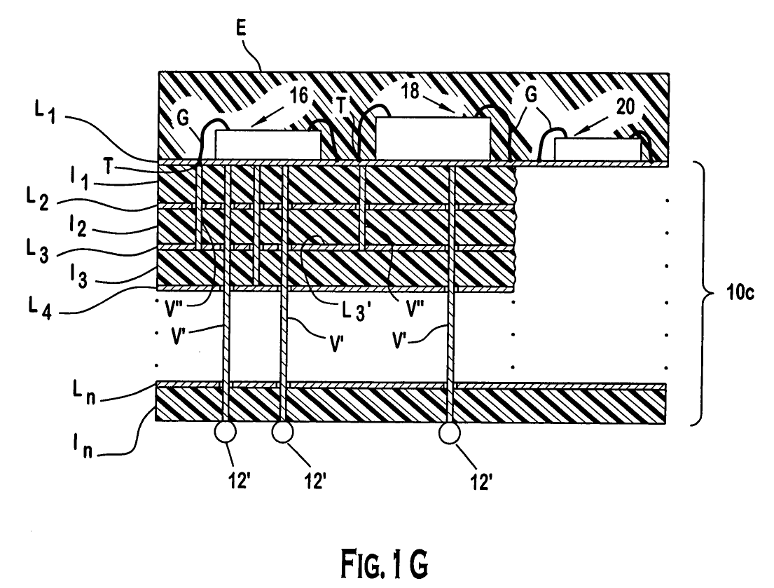

FIGS. 1A-1C show a first embodiment of a high density MCM 10 of the present invention which is a finished package preferably formed of a suitable epoxy compound. The top surface 10a is typically provided with alphanumeric indicia which may be arranged within the dashed lined areas to identify the nature of the MCM as well as other functions and capabilities. 10c represents the multilayered BT substrate, as will be described in detail below. The bottom surface 10d is provided with a plurality of balls arranged in a regular matrix array of x-rows and y-columns. In the embodiment shown, an array of eighteen (18) rows labeled 1-18 and eighteen (18) columns labeled A-H, J-N, P-R and T-V for a total of 324 balls make up the BGA. The diameter of the balls in the embodiment shown is 0.56 mm and the balls extend downwardly from the bottom surface 10d by distance of the order of 0.38 mm. The balls are preferably formed of Sn/Pb.

FIG. 1D is a top plan view of the dies incorporated within the finished package 10 shown, for example, in FIG. 1A, the dies having been shown enlarged as compared with the package shown in FIG. 1A for purposes of clarity.

The embodiment 10 is designed to function as one of a remote terminal (RT), monitor and bus controller (BC), and comprises a protocol die 14, two transceiver dies 16 and 18 and a 64K RAM die 20. Each of the dies 14-20 are bonded to the substrate, which is a high thermal gradient fiber reinforced material (Tg BT) 22 using a suitable conductive epoxy to electrically and mechanically secure the ground plane of each die to the substrate. The terminals of the dies are interconnected with gold wires G bonded at one end to each terminal of the dies 16-20 and at the other end to the multilayer substrate 22 which, although not shown for purposes of clarity, should be understood to be provided with conductive printed wiring for properly interconnecting the circuits. Connections of selected terminals of the dies 16-20 are electrically connected to selected terminals of other ones of the dies 16-20 through selected layers of the multi-layer substrate. After interconnection of all of the circuits, the dies are over-molded employing an epoxy compound that is impervious to moisture. The I/O is achieved by attaching the substrate terminals of the dies 14-20 to selective ones of the balls 12 of the BGA through substrate 10c. In the preferred embodiment, the outer perimeter of the device 10 is 0.815 in.×0.815 in. Since the BGA is provided along the bottom of the package, the board area required is a maximum of the aforesaid outer perimeter which is less than 45% of the board area required by a conventional leaded ceramic device. The device is mounted on a printed circuit board having an array of terminals (not shown) which matches the BGA, for connection to external circuitry; power sources, ground planes and heat conducting planes, for example.

FIG. 1E is a detailed elevational view useful in showing the manner in which one preferred substrate design is produced, such as the substrate utilized for the embodiment 10 shown, for example, in FIGS. 1A-1C. The substrate 10c is comprised of a total of eight (8) conductive layers labeled L₁ through L₆ as well as conductive layers G and VDDL. All of the aforementioned conductive layers are separated by seven (7) insulation layers I₁ through I₇. The insulation layers are preferably 0.0035 inches thick. All of the inner conductive layers L2 through L5, G and VDDL are 0.0007 inches thick. The two outer (i.e., top and bottom) layers L1 and L6 are 0.0014 inches thick and are further provided with layers of the order of 100 to 200 micro inches of nickel and 20 to 30 micro inches of gold for enhancing the gold wire bonding and for Sn/Pb ball attachment of the BGA 12.

Each layer is produced individually and the layers are then stacked upon one another. Insulating layer I₇ is provided with a conductive copper layer L₅ and the bottom, outer layer L₆. These layers are then etched in a conventional manner to remove all of the copper from layers L₅ and L₆ except for the desired printed wiring pattern. Once the desired pattern is etched and the surface is cleaned, holes H are drilled through conductive layer L₅ and insulating layer I₇ in accordance with the hole pattern shown in FIG. 1F. The printed wiring pattern provided on the top surface of insulating layer I₇ has been omitted from FIG. 1F for purposes of simplicity. After the holes H have been drilled, the holes which are marked by a circle are then plated to provide a conductive path through the insulating layer I₇. Each of the remaining insulating layers, except layer I₁, is covered with a thin copper layer, etched and cleaned, then drilled and then plated through selective ones of the drill holes. The layers are then stacked one upon the other in the manner and configuration shown in FIG. 1E. The identical drill pattern shown in FIG. 1F is utilized for drilling and plating the holes in insulating layer I₂. It should be understood that the thick top and bottom conductive layers L₁ and L₆ have printed wiring patterns etched in a similar manner as described above with regard to conductive layers L₅ and L₂. The layers are joined together by application of heat and pressure as is conventional. As a final step, the bottom conductive layer is comprised of circular-shaped “dots” corresponding to the arrangement shown in, for example, in FIG. 1C. The balls 12 of the BGA are placed in a holder having hemispherical recesses with through openings for each ball 12. The holder is vibrated to properly seat each ball 12 in its recess and the holder is placed on and registered with the matrix array of conductive dots on the bottom of layer I₅. The balls are initially perfect spheres and are slightly flattened in the region where they are joined to an associated “dot” by application of heat of a sufficient temperature for a sufficient time interval.

The dies, such as, for example, the dies 16 through 20 shown in FIG. 1D are mounted upon the upper surface of insulating layer I₁ having the printed wiring layer L₁ by a suitable conductive epoxy. FIG. 1G shows a portion of dies 16-20 in which the gold wires G of a diameter of the order of 0.001 inches are connected between dies 16-20 and selected conductive pads T on the thicker top layer L₁ of the substrate 10C. It should be understood that the layers and terminals are greatly enlarged as compared with their actual size for purposes of clarity. Layer L₁ is deposited on insulating layer I₁. Layer L₂ is a conductive copper layer deposited on layer I₂, a dielectric layer and so forth with the conductive copper and dielectric layers being arranged in alternating fashion as shown in FIG. 1E. Vertically aligned conductive members hereinafter referred to as micro vias V, make electrical connections at selective layers for interconnecting components in the dies 16-20 as well as providing ground vias, electrical connection vias to external terminals/components and thermal vias. The thermal vias such as V′, for example, directly connect those portions of the dies 16, 18 which generate the greatest amount of heat within dies 16, 18 and are thus directly connected to a selected ball or balls 12′ for directly conducting heat preferably over the shortest practical path in order to convey heat away from the regions of high heat generation. The balls 12′ of the BGA carrying the heat away from the device 10 are connected to a conductive plane on the substrate (not shown) upon which the device 10 is mounted for conducting heat away from the device 10. The vias conducting heat away from the high heat regions of the dies are preferably filled with conductive material such as solder. The holes conducting heat are preferably of the order of 0.004″ in diameter, while the holes for electrically coupling electrical terminals are preferably of the order of 0.004″ in diameter. Vias V″ connect one terminal T of die 16 to one terminal T′ of die 18, vias V″ being electrically connected through a printed wiring pattern L₂′ on insulating layer I₂.

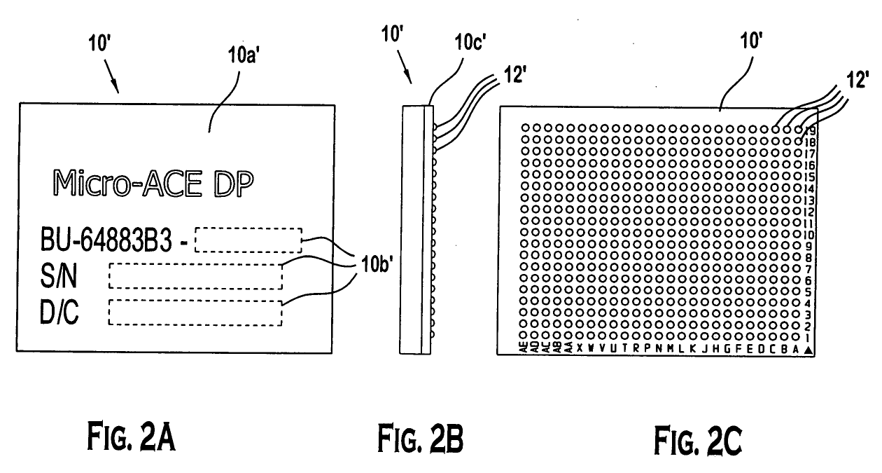

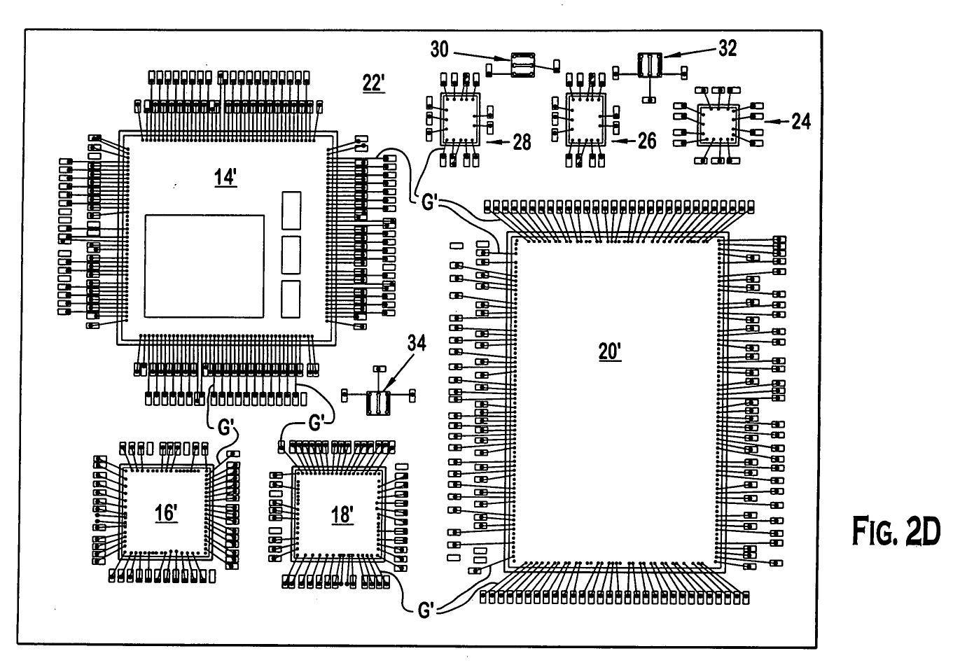

FIGS. 2A-2C show another preferred embodiment 10′ of the present invention wherein the main difference as shown in FIGS. 2A-2C is the overall size of the completed package, the thickness of the package 10′ being substantially identical to the thickness of the package 10 as shown FIGS. 2B and 1B while the outer dimensions are different. The embodiment 10′ may also function as an RT, BC or monitor. In the embodiment 10′ the package has an outer perimeter of 1.10 in.×0.850 in. and the BGA of the balls 12 in the embodiment 10′ has a regular matrix array comprised of a total of 475 solder balls 12, the solder balls of both embodiments preferably being formed of Sn/Pb. The balls 12 in both embodiments preferably have substantially the same diameter.

The thermal resistance in both embodiments 10 and 10′ are comparable with a maximum of 15° C. per watt (C/W). There are two semiconductor devices in each of the embodiments 10 and 10′ that produce the bulk of the heat generated. This heat is dissipated through several solder balls which are arranged directly under each of the heat devices, together with additional thermal vias connected to ground planes within the FR4 substrate and brought out to other solder balls of the BGA. The embodiment 10′, as shown in FIG. 2D, is comprised of a protocol chip 14′, two transceiver chips 16′, 18′ and a 128K dual port RAM 20′, one quad buffer 24 with tri-state outputs and two nine-bit parity checkers 26 and 28. Three 2.4K ohm thin film resisters are used for pull ups. These dies are likewise bonded to the substrate 22′ employing a conductive epoxy and are similarly interconnected with gold wires G′ bonded between the semiconductor devices 14′-20′ and 24-28 and terminals T on the multilayer substrate 22′. The assembly is similarly over-molded employing an epoxy compound.

The terminals T are connected to selected layers L₁-L_{N} and vias V to obtain the appropriate electrical connections between and among the components of the device and to provide heat conduction of maximum efficiency away from the high heat producing regions by dissipating this heat through a plurality of solder balls 12 arranged directly under each of the heat producing devices as well as employing additional thermal vias connected to ground planes in the BT substrate which ground planes extend to selected solder balls 12 of the BGA.

What is claimed is:

1. A multi-die package assembly, comprising
a multilayer substrate comprised of a plurality of conductive layers with a plurality of dielectric layers in alternating fashion;
a plurality of dies arranged on a top surface of said substrate, each die having a plurality of die terminals selectively coupled to substrate terminals of said top surface;
a plurality of conductive balls arranged on a bottom surface of said substrate in a matrix of rows and columns comprising a ball grid array (BGA);
at least one pair of electrical connection vias extending in a direction transverse to said layers and electrically coupled to at least one selected conductive layer for selectively coupling die terminals of different dies to one another and at least another transverse aligned via coupled to at least a given one of said balls for providing an electrical connection of a die terminal to an external circuit; and
heat conducting vias extending in a direction transverse to said layers and insulated from said conductive layers for coupling high heat generating regions of said dies to heat conducting balls other than said electrical connection balls for conducting heat away from said dies.

2. The assembly of claim 2 wherein said heat conducting vias extend directly from said high heat generating areas to said heat conducting balls.

3. The package assembly of claim 1 wherein said package assembly is enclosed in an epoxy whereby said balls in said BGA are exposed at a bottom surface of said assembly for electrical connection to external circuitry.

4. The assembly of claim 1 wherein said balls are formed of an Sn/Pb material.

5. The assembly of claim 1 wherein said substrate is formed of a high thermal gradient (Tg), BT material.

6. The assembly of claim 1 wherein said dies are bonded to said substrate employing a conductive epoxy.

7. The assembly of claim 1 wherein selected conductive layers of said substrate conduct heat away from said substrate.

8. The assembly of claim 1 wherein terminals of said dies are connected to terminals on said substrate by gold wire.

9. The assembly of claim 1 wherein said dies include at least one transceiver, a memory (RAM) and a protocol logic chip.

10. The assembly of claim 1 wherein said dies are selected to operate as a bus controller (BC).

11. The assembly of claim 1 wherein said dies are selected to operate as a remote terminal (RT).

12. The assembly of claim 1 wherein said dies are selected to operate as a monitor.

13. A method for producing a multi-die package assembly which provides a significantly reduced footprint, comprising:
forming a multi-layer substrate comprised of individual insulating layers each having a conductive layer;
removing at least a portion of each conductive layer to form a printed wiring pattern;
drilling holes in each insulating layer in accordance with a given drilling pattern;
through-plating selected ones of the drill holes in said insulating layers to provide a conductive path between the upper and lower surfaces of each drilled opening;
stacking said insulating layers one upon the other in a given pattern;
mounting die assemblies on a top surface of a top insulating layer of said stack of layers;
wire bonding selected terminals of said dies to selected conductive terminals on said top surface of said top insulating layer;
providing a ball grid array on a printed wiring pattern provided on a bottom surface of a bottom insulating layer;
wherein at least one terminal of one of said plurality of dies is electrically connected to at least one terminal of another one of said dies by an electrical path extending between said one terminal, at least one plated through hole, at least one printed wiring pattern of one of said layers of said substrate beneath said top layer, another plated hole and said other terminal of said other one of said dies; and
wherein at least selected plated holes of all of said insulating layers form a continuous heat conducting path between a heat generating region of one of said dies and at least one ball of said BGA.

14. The method of claim 13 further comprising:
providing a conductive layer on the top surface with a thin layer of gold; and
bonding gold wires between terminals on said dies and said gold layers on said top surface.

15. The method of claim 13 further comprising:
providing conductive layers on said top and bottom surfaces that are thicker than the inner conductive layers.

16. The method of claim 13 further comprising:
providing a conductive layer having a given pattern on the bottom surface with a layer of gold; and
selectively attaching balls of said BGA to given portions of said given pattern.
